(19) United States
(12) Patent Application Publication
(10) Pub. No.: US 2015/0243846 A1
(43) Pub. Date: Aug. 27, 2015

(54) LIGHT EMITTING DEVICE PACKAGE

(71) Applicant: SAMSUNG ELECTRONICS CO., LTD., Suwon-si (KR)

(72) Inventors: Yong-min KWON, Seoul (KR); Sung-jun IM, Yongin-si (KR); Kyoung-jun KIM, Yongin-si (KR)

(21) Appl. No.: 14/631,611

(22) Filed: Feb. 25, 2015

(30) Foreign Application Priority Data
Feb. 26, 2014 (KR) 10-2014-0022883

(51) Int. Cl. H01L 33/38; H01L 33/58; H01L 33/32; H01L 33/56; H01L 33/62; H01L 33/06

(52) U.S. Cl. CPC H01L 33/382; H01L 33/62; H01L 33/06; H01L 33/32; H01L 33/56; H01L 33/58

(57) ABSTRACT

A light emitting device package including a first electrode pad and a second electrode pad formed to contact a lower surface of a light emitting device; a bonded insulating layer pattern formed to at least partially cover side surfaces and lower surfaces of the first electrode pad and the second electrode pad; a substrate, in which via holes are formed which penetrate the substrate from a first surface of the substrate that contacts a lower surface of the bonded insulating layer pattern to a second surface of the substrate that is opposite to the first surface; a through-electrode disposed in each via hole and contacting the lower surface of one of the respective first electrode pad and the second electrode pad; and a through-electrode insulating layer formed between the through-electrode and the substrate, and having an upper surface that contacts a portion of the lower surface of the bonded insulating layer pattern.

### CROSS-REFERENCE TO RELATED APPLICATION

This application claims the benefit of Korean Patent Application No. 10-2014-0022883, filed on Feb. 26, 2014, in the Korean Intellectual Property Office, the disclosure of which is incorporated herein in its entirety by reference.

### BACKGROUND

The disclosure relates to a light emitting device package, and more particularly, to a light emitting device package including a through-electrode that penetrates through a substrate.

A light emitting device package is used in small electronic appliances, interior goods, large-sized back light units (BLUs), general illumination devices, electronic devices, and the like. Products using a light emitting device package need to increase a design degree of freedom. For example, a width of a BLU has to be reduced to make a slim light emitting diode (LED) TV and a size of a light emitting device package needs to be reduced in order to manufacture various types of illumination and electronic devices.

### SUMMARY

The present disclosure provides a light emitting device package including a through-electrode for reducing a size thereof and a size of a product including the light emitting device package, wherein processes for forming an insulating layer on the through-electrode may be simplified and a step coverage problem caused by chemical vapor deposition (CVD) may be prevented.

According to an aspect of the present disclosure, there is provided a light emitting device package including: a light emitting device; a first electrode pad and a second electrode pad formed to contact a lower surface of the light emitting device; a bonded insulating layer pattern formed to at least partially cover side surfaces and lower surfaces of the first electrode pad and the second electrode pad; a substrate, in which via holes are formed which penetrate the substrate from a first surface of the substrate that contacts a lower surface of the bonded insulating layer pattern to a second surface of the substrate that is opposite to the first surface; a through-electrode disposed in each via hole and contacting the lower surface of one of the respective first electrode pad and the second electrode pad; and a through-electrode insulating layer formed between the through-electrode and the substrate, and having an upper surface that contacts a portion of the lower surface of the bonded insulating layer pattern.

The through-electrode insulating layer may be formed on the first surface of the substrate.

The upper surface of the through-electrode insulating layer may be spaced apart from the first electrode pad and the second electrode pad.

The bonded insulating layer pattern may be disposed between the first and second electrode pads and the through-electrode insulating layer.

The through-electrode insulating layer may be formed of a silicon oxide layer that is thermally oxidated.

The through-electrode insulating layer may be formed between the substrate and the through-electrode to a uniform thickness.

A thickness of the through-electrode insulating layer may be less than a thickness of the bonded insulating layer pattern.

The light emitting device may further include an extended through-electrode insulating layer arranged between the through-electrode and the second surface of the substrate, wherein a thickness of the extended through-electrode insulating layer may be greater than a thickness of the through-electrode insulating layer.

The light emitting device may include: a first nitride-based semiconductor layer; a second nitride-based semiconductor layer disposed on the first nitride-based semiconductor layer; and an active layer disposed between the first nitride-based semiconductor layer and the second nitride-based semiconductor layer, wherein the active layer is formed to have a multi quantum well (MQW).

The first electrode pad may contact a part of a lower surface of the first nitride-based semiconductor layer, and the second electrode pad may contact another part of the lower surface of the first nitride-based semiconductor layer and may be electrically connected to the second nitride-based semiconductor layer by penetrating through the first nitride-based semiconductor layer and the active layer.

The light emitting device may further include a lens unit surrounding an upper surface and side surfaces of the light emitting device, and contacting a part of an upper surface of the bonded insulating layer pattern.

According to another aspect of the present disclosure, provided is a light emitting device package including: a light emitting device; at least two electrode pads formed on a lower surface of the light emitting device; a substrate disposed on a lower portion of the light emitting device, and including via holes that extend between a first surface of the substrate facing the light emitting device and a second surface of the substrate that is opposite to the first surface; a through-electrode disposed in each of the via holes and contacting a part of a lower surface of a respective one of the at least two electrode pads; a bonded insulating layer pattern formed between the substrate and the light emitting device, and at least partially covering side surfaces and the lower surfaces of the at least two electrode pads; and a through-electrode insulating layer formed between a lower surface of the bonded insulating layer pattern and the substrate.

The through-electrode insulating layer may be formed between the substrate and the through-electrode, and on the first surface and the second surface of the substrate.

The through-electrode insulating layer may be formed between the substrate and the through-electrode, and on the first surface and the second surface to a uniform thickness.

The through-electrode may extend from the via hole to cover a part of the second surface.

### BRIEF DESCRIPTION OF THE DRAWINGS

Exemplary embodiments of the disclosure will be more clearly understood from the following detailed description taken in conjunction with the accompanying drawings in which:

FIG. 1 is a cross-sectional view of a light emitting device package according to an embodiment of the present disclosure;

FIG. 2 is a cross-sectional view of a light emitting device package according to another embodiment of the present disclosure;

FIGS. 3 through 7 are cross-sectional views illustrating processes of manufacturing a light emitting device package according to an embodiment of the present disclosure;

FIGS. 8 through 12 are cross-sectional views illustrating processes of manufacturing a light emitting device package according to another embodiment of the present disclosure; and

FIG. 13 is a cross-sectional view of a dimming system including a light emitting device package according to an embodiment of the present disclosure.

### DETAILED DESCRIPTION OF THE EMBODIMENTS

Hereinafter, the present disclosure will be described more fully with reference to the accompanying drawings, in which exemplary embodiments of the disclosure are shown. This disclosure may, however, be embodied in many different fowls and should not be construed as limited to the exemplary embodiments set forth herein. Rather, these embodiments are provided so that this disclosure will be thorough and complete, and will fully convey the disclosure to one of ordinary skill in the art. Sizes of components in the drawings may be exaggerated for convenience of explanation.

It will be understood that when an element is referred to as being “on” or in “contact” with another element, it may be directly connected to or in direct contact with the other element, or intervening elements may be present. In contrast, when an element is referred to as being “directly on” or “directly contacting” another element or layer, there are no intervening elements present. Other expressions for describing relationships between elements, for example, “between” and “immediately between” may also be interpreted similarly.

Spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures.

It will also be understood that, although the terms first, second, etc. may be used herein to describe various elements, these elements should not be limited by these terms. These terms are used only to distinguish one element from another. For example, a first element could be termed a second element, and, similarly, a second element could be termed a first element, without departing from the scope of the present disclosure.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms used herein have the same meaning as commonly understood by one of ordinary skill in the art to which exemplary embodiments belong. As used herein, the tem “and/or” includes any and all combinations of one or more of the associated listed items. Expressions such as “at least one of,” when preceding a list of elements, modify the entire list of elements and do not modify the individual elements of the list.

Hereinafter, exemplary embodiments of the present disclosure will be described with reference to accompanying drawings.

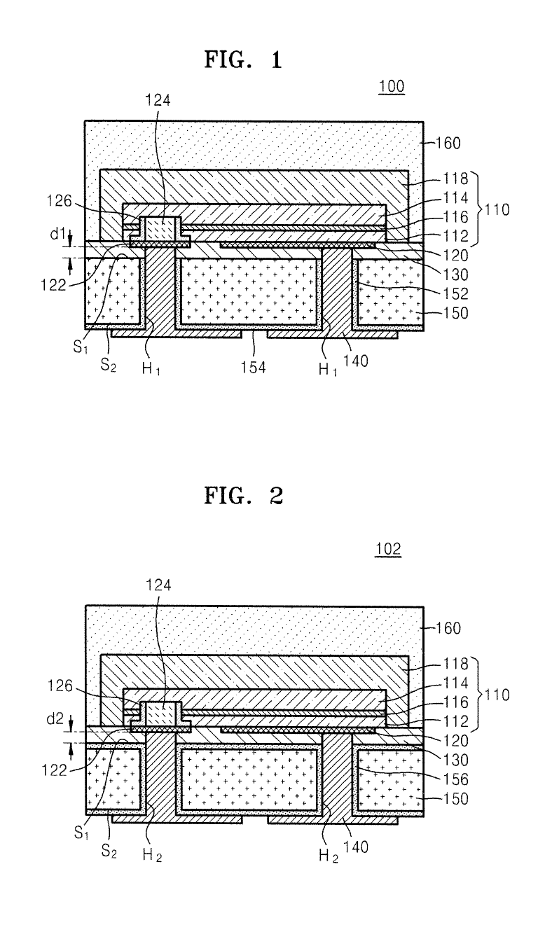

FIG. 1 is a cross-sectional view of a light emitting device package 100 according to an embodiment of the present disclosure.

Referring to FIG. 1, the light emitting device package 100 has a structure in which a light emitting device 110 is bonded to a substrate 150. A bonded insulating layer pattern 130 is formed between the light emitting device 110 and the substrate 150. A first electrode pad 120 and a second electrode pad 122 are configured to contact a lower surface of the light emitting device 110 and to be surrounded by the bonded insulating layer pattern 130. A through-electrode 140 penetrates through the substrate 150 from an upper surface that contacts a lower surface of the bonded insulating layer pattern 130 to a lower surface. A through-electrode insulating layer 152 may be interposed between the through-electrode 140 and the substrate 150, and an upper surface of the through-electrode insulating layer 152 contacts a lower surface of the bonded insulating layer pattern 130. The upper surface of the through-electrode insulating layer 152 and the first and second electrode pads 120 and 122 are separated by a predetermined distance from each other. A lens unit 160 may be formed to cover an upper surface and side surfaces of the light emitting device 110.

The light emitting device 110 includes a first nitride-based semiconductor layer 112, a second nitride-based semiconductor layer 114, and an active layer 116. According to an embodiment of the present disclosure, the light emitting device 110 may further include a phosphor resin layer 118. The first nitride-based semiconductor layer 112 is formed on the bonded insulating layer pattern 130 toward the upper surface of the bonded insulating layer pattern 130, the second nitride-based semiconductor layer 114 is formed on the first nitride-based semiconductor layer 112, and the active layer 116 may be disposed between the first nitride-based semiconductor layer 112 and the second nitride-based semiconductor layer 114.

The first nitride-based semiconductor layer 112 and the second nitride-based semiconductor layer 114 may include at least one semiconductor material selected from the group consisting of GaN, InGaN, InN, AlN, AlGaN, AlInN, and AlZnGaN. In one or more embodiments, an irregular pattern may be formed on an upper surface of the second nitride-based semiconductor layer 114, which faces a lower surface of the phosphor resin layer 118.

The first electrode pad 120 that is connected to the first nitride-based semiconductor layer 112 is formed on a part of an exposed lower surface of the first nitride-based semiconductor layer 112. The second electrode pad 122 is formed on a part of the lower surface of the first nitride-based semiconductor layer 112 on which the first electrode pad 120 is not formed. A second electrode 124 is connected to the second nitride-based semiconductor layer 114 by penetrating through the first nitride-based semiconductor layer 112 and the active layer 116. In one or more embodiments, the second electrode 124 may be formed integrally with the second electrode pad 122. An electrode pad insulating layer 126 is disposed between the side surfaces of the second electrode 124 and a partial upper surface of the second electrode pad 122, and, the first nitride-based semiconductor layer 112 and the active layer 116, so as to insulate the second electrode pad 122 and the second electrode 124 from the first nitride-based semiconductor layer 112 and the active layer 116.

The light emitting device 110 may include the phosphor resin layer 118 covering the upper surface of the second nitride-based semiconductor layer 114. In an exemplary embodiment of the present disclosure, the phosphor resin layer 118 may cover the first nitride-based semiconductor layer 112, the active layer 116, and side surfaces of the second nitride-based semiconductor layer 114.

The substrate 150 includes a via hole H1 penetrating from a first surface S1 contacting the lower surface of the bonded insulating layer pattern 130 to a second surface S2 that is opposite to the first surface S1, the through-electrode 140 formed to fill the via hole H1, and the through-electrode insulating layer 152 formed between the through-electrode 140 and the substrate 150. The through-electrode 140 penetrates through the substrate 150 through the via hole H1, and may cover a part of the second surface S2 of the substrate 150. In an exemplary embodiment of the present disclosure, the through-electrode 140 may be a through silicon via (TSV).

The through-electrode insulating layer 152 is formed on an inner surface of the via hole H1 in the substrate 150, and may have a uniform thickness in the substrate 150. The through-electrode insulating layer 152 may be formed as a silicon oxide layer (SiO₂), a silicon nitride layer (SiN), or a combination thereof. In the exemplary embodiment of the present disclosure, the through-electrode insulating layer 152 may be formed of SiO₂ that is thermally oxidated. If the through-electrode insulating layer 152 is formed of thermally oxidated SiO₂, a silicon oxidated film may be formed on inner and outer portions of the via hole H1 to a predetermined thickness.

In the exemplary embodiment of the present disclosure, an extended through-electrode insulating layer 154 may be formed on the second surface S2 of the substrate 150. The extended through-electrode insulating layer 154 may be formed of the same material as that of the through-electrode insulating layer 152. A thickness of the extended through-electrode insulating layer 154 may be different from that of the through-electrode insulating layer 152. For example, the thickness of the extended through-electrode insulating layer 154 may be greater than that of the through-electrode insulating layer 152. In the exemplary embodiment of the present disclosure, the thickness of the through-electrode insulating layer 152 may be 80% of that of the extended through-electrode insulating layer 154 or greater, or may be substantially the same as that of the through-electrode insulating layer 152.

The light emitting device package 100 has a structure in which the light emitting device 110 and the substrate 150 are bonded to each other via the bonded insulating layer pattern 130. The bonded insulating layer pattern 130 exposes the first and second electrode pads 120 and 122 formed thereon to contact the lower surface of the light emitting device 110, and the bonded insulating layer pattern 130 may be formed on the first surface SI except for the via hole H1 area. A partial lower surface of the bonded insulating layer pattern 130 may be configured to contact the upper surface of the through-electrode insulating layer 152.

The lens unit 160 covers a partial upper surface of the bonded insulating layer pattern 130, and also may cover the upper and side surfaces of the light emitting device 110. The lens unit 160 may be formed of at least one selected from a group consisting of silicon resin, epoxy resin, plastic resin, and glass. In the present disclosure, the lens unit 160 is formed with a flat rectangular shape; however, the lens unit 160 may have a curve, that is, an upper surface of the lens unit 160 may be convex upward or concave downward.

The light emitting device package 100 according to exemplary embodiments of the present disclosure may include the through-electrode 140 that extends from the first surface S1 to the second surface S2 of the substrate 150 within the via hole H1 in the substrate 150, and the through-electrode insulating layer 152 may be formed between the through-electrode 140 and the substrate 150. The through-electrode insulating layer 152 is formed on the inner side surface of the via hole H1 in the substrate 150 to a uniform thickness, and the upper surface of the through-electrode insulating layer 152 is formed to contact the lower surface of the bonded insulating layer pattern 130. The upper surface of the through-electrode insulating layer 152 is separated by a first distance dl from the lower surface of the first electrode pad 120 and the second electrode pad 122. As will be described with reference to FIG. 4, the through-electrode insulating layer 152 may be formed by thermally oxidating the substrate 150, and thus may have a different material and density from those of the bonded insulating layer pattern 130. Also, a difference between the thickness of the through-electrode insulating layer 152 and the thickness of the extended through-electrode insulating layer 154 may be reduced. According to an exemplary embodiment of the present disclosure, the thickness of the through-electrode insulating layer 152 may be substantially the same as that of the extended through-electrode insulating layer 154, or may be 80% or greater of the thickness of the extended through-electrode insulating layer 154. If the insulating layer is formed in the space defined by the via hole H1 formed in the substrate 150, that is, the inner side surface of the via hole H1, by using a chemical vapor deposition (CVD) method, a step coverage characteristic is not good and the insulating layer may be formed unevenly. Thus, when the through-electrode insulating layer 152 is formed by thermally oxidating the substrate 150, an unstable electric insulating performance caused by the uneven thickness of the insulating layer may be reduced. Also, when the insulating layer is formed by using the CVD method, the insulating layer is also formed on the lower surfaces of the first electrode pad 120 and the second electrode pad 122, and accordingly, an additional process for removing the insulating layer formed on the lower surfaces of the first electrode pad 120 and the second electrode pad 122 may be omitted according to the present disclosure. Thus, the manufacturing processes may be simplified.

FIG. 2 is a cross-sectional view of a light emitting device package 102 according to another exemplary embodiment of the present disclosure.

Referring to FIG. 2, similar to the light emitting device package 100 shown in FIG. 1, the light emitting device package 102 includes the light emitting device 110, the first electrode pad 120, the second electrode pad 122, the bonded insulating layer pattern 130, the through-electrode 140, and the substrate 150. The light emitting device package 102 is different from the light emitting device package 100 in view of a through-electrode insulating layer 156. That is, similar to the FIG. 1 embodiment, the through-electrode insulating layer 156 is formed between the through-electrode 140 and the substrate 150, and on the second surface S2 of the substrate 150, but is additionally formed on the first surface S1 of the substrate 150. The through-electrode insulating layer 156 formed on the first surface S1 of the substrate 150 is separated by a second distance d2 from the first electrode pad 120 and the second electrode pad 122. The through-electrode insulating layer 156 is formed on the first surface S1 and the second surface S2 of the substrate 150, and between the through-electrode 140 and the substrate 150 to a uniform thickness.

The through-electrode insulating layer 156 is formed on the first surface S1 of the substrate 150, as well as between the second surface S2 of the substrate 150 and the through-electrode 140, because the substrate 150 is thermally oxidated to form the through-electrode insulating layer 156 before performing a process of connecting the substrate 150 to the light emitting device 110 via the bonded insulating layer pattern 130. This will be described later with reference to FIG. 9.

The light emitting device package 102 shown in FIG. 2 includes the through-electrode insulating layer 156 that is formed by thermally oxidating the substrate 150, and thus, effects of the light emitting device package 100 of FIG. 1 may be obtained, and descriptions thereof are omitted.

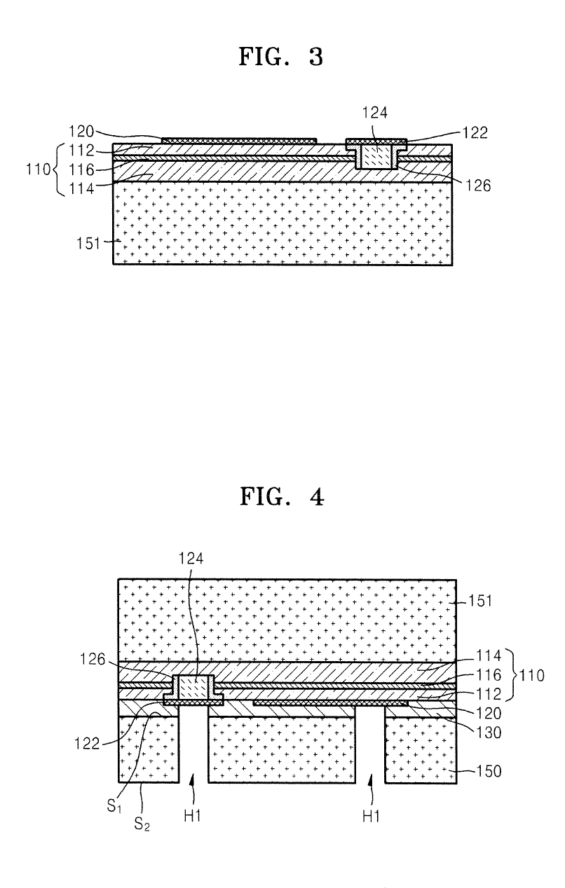

FIGS. 3 through 7 are cross-sectional views illustrating a method of manufacturing the light emitting device package 100 of FIG. 1.

Referring to FIG. 3, the light emitting device 110 is formed on a growth substrate 151. The growth substrate 151 may include at least one of insulating materials, conductive materials, or semiconductor materials such as Si, Ge, SiC, GaN, GaAs, MN, BN, GaP, and sapphire (Al₂O₃). Although not shown in the drawings, an irregular pattern may be formed on an upper surface of the growth substrate 151.

The light emitting device 110 may be formed on the growth substrate 151. The light emitting device 110 may include a plurality of nitride-based semiconductor layers formed in one of an n-p junction structure, a p-n junction structure, an n-p-n junction structure, or a p-n-p junction structure based on the growth substrate 151. In an exemplary embodiment of the present disclosure, the light emitting device 110 may have an n-p junction structure.

The light emitting device 110 may include the second nitride-based semiconductor layer 114, the active layer 116, and the first nitride-based semiconductor layer 112 that are sequentially stacked. The light emitting device 110 may be formed by using at least one method selected from the group consisting of an electron beam evaporation method, a physical vapor deposition (PVD) method, a CVD method, a plasma enhanced CVD (PECVD) method, a plasma laser deposition (PLD) method, a sputtering method, a metal organic chemical vapor deposition (MOCVD) method, and a molecular beam epitaxy (MBE) method.

The light emitting device 110 may be configured by growing a nitride-based semiconductor, for example, InN, AlN, InGaN, AlGaN, InGaAlN, etc. The first nitride-based semiconductor layer 112 and the second nitride-based semiconductor layer 114 may include different impurities so as to have different conductivity types from each other. The first nitride-based semiconductor layer 112 may include p-type impurities, and the second nitride-based semiconductor layer 114 may include n-type impurities. In the exemplary embodiment of the present disclosure, the first nitride-based semiconductor layer 112 and the second nitride-based semiconductor layer 114 may respectively include group III-V compound materials and GaN-based materials.

The active layer 116 has a lower energy bandgap than those of the first nitride-based semiconductor layer 112 and the second nitride-based semiconductor layer 114, and thus, light emission may be sufficiently performed. The active layer 116 may emit light of various wavelengths, for example, an infrared ray, a visible ray, or an ultraviolet ray. The active layer 116 may include a group III-V compound material, for example, InGaN or AlGaN. Also, the active layer 116 may include a single quantum well (SQW) or a multi quantum well (MQW). In the exemplary embodiment of the present disclosure, the active layer 116 may include the MQW.

The first electrode pad 120 is formed on a partial upper surface of the light emitting device 110. The first electrode pad 120 may be formed of at least one metal material selected from the group consisting of Au, Ag, Al, Ni, Cr, Pd, and Cu. The first electrode pad 120 may be formed of a single material or an alloy, by using a deposition method, a sputtering method, or a plating method.

The first nitride-based semiconductor layer 112 and the active layer 116 are partially removed to form a removed region, and the second electrode 124 is formed on the removed region. The first nitride-based semiconductor layer 112 and the active layer 116 may be removed by using an inductivity coupled plasma reactive ion etching (ICP-RIE) method, a wet etching method, or a dry etching method. The second electrode 124 may be electrically connected to the second electrode pad 122.

The second electrode pad 122 is formed on a portion of the upper surface of the light emitting device 110, on which the first electrode pad 120 is not formed. The second electrode pad 122 may be formed of the same material as that of the first electrode pad 120 by using the same method as that of the first electrode pad 120. The second electrode pad 122 may be electrically connected to the second nitride-based semiconductor layer 114 via the second electrode 124.

Referring to FIG. 4, the light emitting device 110 and the growth substrate 151 shown in FIG. 3 are turned upside down so as to form the bonded insulating layer pattern 130 and the substrate 150.

The bonded insulating layer pattern 130 is formed to contact the lower surface of the light emitting device 110 and to cover lower and side surfaces of the first electrode pad 120 and the second electrode pad 122. The bonded insulating layer pattern 130 may be formed by using the CVD method or the PVD method. In the present exemplary embodiment, the bonded insulating layer pattern 130 may be formed of a silicon oxide layer, a silicon nitride layer, or a combination thereof. Before forming the bonded insulating layer pattern 130, the lower surface of the light emitting device 110 may be treated by using plasma or by a chemical mechanical polishing (CMP) process in order to increase a bonding strength of the bonded insulating layer pattern 130.

The substrate 150 is bonded to the lower surface of the bonded insulating layer pattern 130. The substrate 150 may be formed of at least one semiconductor material selected from the group consisting of Si, Ge, SiGe, and SiC. The via hole H1 that penetrates the substrate 150 from the first surface S1 contacting the bonded insulating layer pattern 130 to the second surface S2 that is opposite to the first surface S1, and that extends to the lower surfaces of the first electrode pad 120 and the second electrode pad 122, is formed. The via hole H1 may be formed by etching the substrate 150 and the bonded insulating layer pattern 130. In particular, the substrate 150 and the bonded insulating layer pattern 130 may be anisotropically etched by using the wet etching method or the dry etching method to form the via hole H1. In the drawings of the present specification, the via hole H1 is shown as being straight in a direction perpendicular to the substrate 150; however, the via hole H1 may have an inner diameter that increases from the first surface S1 toward the second surface S2 according to an etching ratio and a directivity during the etching of the substrate 150.

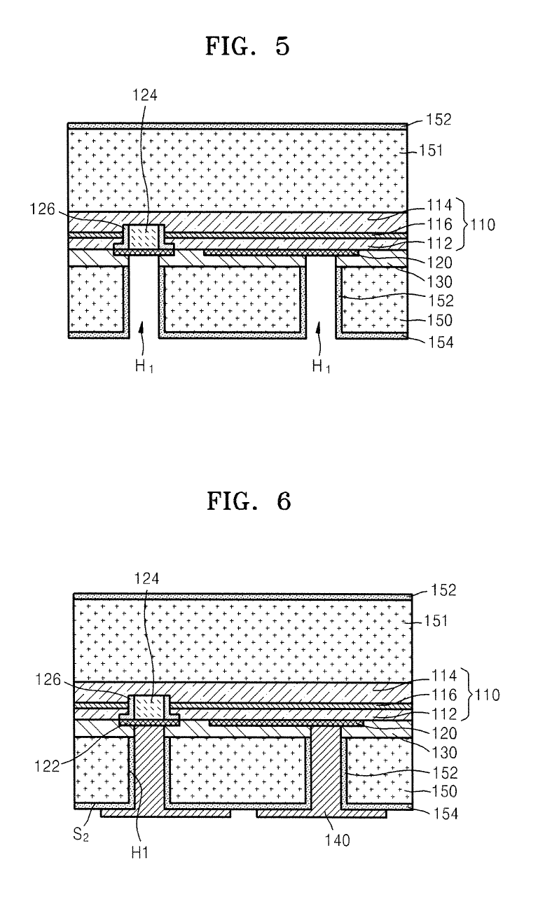

Referring to FIG. 5, the through-electrode insulating layer 152 is formed on the surface of the substrate 150 which includes the via hole H1. According to the present exemplary embodiment of the present disclosure, the substrate 150 may be a conductive substrate, and the through-electrode insulating layer 152 may be formed to electrically insulate the substrate 150 from the through-electrode 140 that is conductive. The through-electrode insulating layer 152 may be formed on the surface of the substrate 150 within the via hole H1 and the second surface S2 of the substrate 150. The through-electrode insulating layer 152 may be formed as a silicon oxide layer, a silicon nitride layer, or a combination thereof.

In the exemplary embodiment of the present disclosure, the through-electrode insulating layer 152 may be formed by thermally oxidating the substrate 150. The above thermal oxidation method may include exposing the substrate 150 to oxygen or vapor under a high temperature of about 800° C. to about 1200° C., and causing a chemical reaction on the surface of the silicon forming the substrate 150. When comparing the thermal oxidation method with the deposition method including CVD, the through-electrode insulating layer 152 formed by thermal oxidation has less unevenness in thickness such as step coverage, and may be formed as an oxide layer having a relatively small and even thickness. As described above with reference to FIG. 1, since the through-electrode insulating layer 152 is formed by the thermal oxidation method, problems caused by an uneven thickness of the insulating layer may be addressed. Moreover, unlike the deposition method, the insulating layer is not formed on the bonded insulating layer pattern 130, the lower surfaces of the first electrode pad 120 and the second electrode pad 122, and thus, an additional process of removing the insulating layer may be omitted, so that the manufacturing processes may be simplified.

Owing to the thermal oxidation method, the extended through-hole electrode insulating layer 154 may be formed on the second surface S2 of the substrate 150. The extended through-electrode insulating layer 154 may be formed of the same film material as that of the through-electrode insulating layer 152. The thickness of the extended through-electrode insulating layer 154 may be different than that of the through-electrode insulating layer 152. For example, the thickness of the extended through-electrode insulating layer 154 may be greater than that of the through-electrode insulating layer 152.

Referring to FIG. 6, the through-electrode 140 is formed to fill the via hole H1 and has an upper surface that contacts the lower surfaces of the first electrode pad 120 and the second electrode pad 122.

The through-electrode 140 is formed in a space defined by the through-electrode insulating layer 152 in the via hole H1 and extends over a portion of the second surface S2 of the substrate 150. In the exemplary embodiment of the present disclosure, the through-electrode insulating layer 152 is formed on the second surface S2 of the substrate 150, and thus, the through-electrode insulating layer 152 may be disposed on the second surface S2 of the substrate 150, on which the through-electrode 140 is formed.

The through-electrode 140 may be formed by forming a metal seed layer within a space defined by the through-electrode insulating layer 152 in the via hole H1 by using a sputtering method, and plating a metal material on the metal seed layer. After forming the metal seed layer, a photomask process may be performed on a portion other than the lower surface of the extended through-electrode insulating layer 154, on which the through-electrode 140 is to be formed, so that the portion shielded by the photomask may not be plated with the metal material. After the metal seed layer is plated with the metal material, the photomask may be removed so that a plurality of through-electrodes 140 may be spaced apart by predetermined distances from one another.

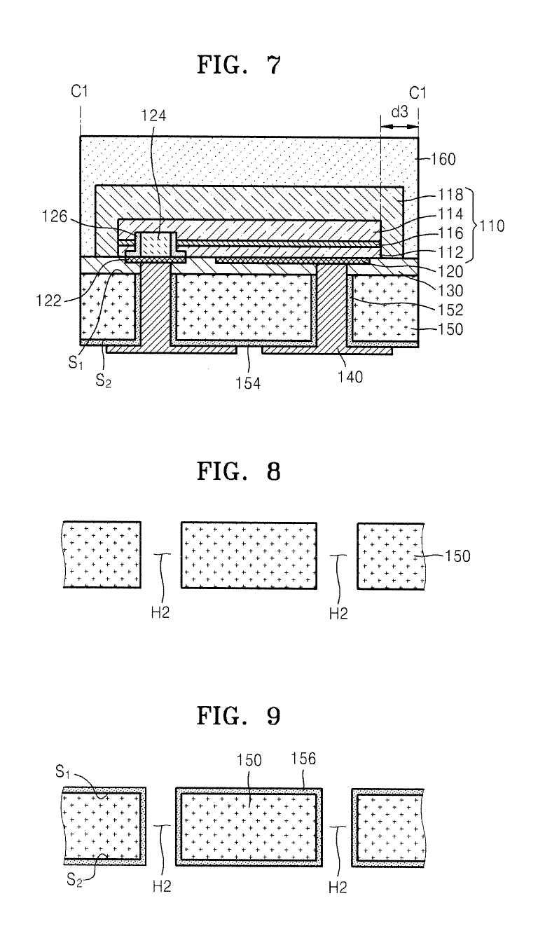

Referring to FIG. 7, the growth substrate 151 is removed, and a side wall of the light emitting device 110 is removed by etching to a third distance d3 from the wall surface. Then, the phosphor resin layer 118 and the lens unit 160 are formed.

In the exemplary embodiment of the present disclosure, the growth substrate 151 may be a sapphire substrate, and thus, the growth substrate 151 may be removed by using an etching method including wet etching and/or dry etching, or using a laser lift off method. In one or more exemplary embodiments of the present disclosure, on the upper surface of the second nitride-based semiconductor layer 114, which is exposed when removing the growth substrate 151, an irregular pattern may be formed.

After removing the growth substrate 151, a part of the light emitting device 110 is etched to a predetermined depth from the side wall of the light emitting device 110 to be narrower than a width of the bonded insulating layer pattern 130. When the light emitting device 110 is fabricated at a wafer level, the light emitting device 110 includes the first electrode pad 120 and second electrode pad 122. A part of the light emitting device 110 may be removed so as to be spaced apart from neighboring light emitting devices 110 by twice the third distance d3.

After performing the etching process, the phosphor resin layer 118 covering the upper and side surfaces of the light emitting device 110 is formed. The phosphor resin layer 118 may be formed of a phosphor material that may convert light emitted from the light emitting device 110 to light of a different color, for example, white light. The phosphor material may be at least one selected from the group consisting of yttrium aluminum garnet (YAG), terbium aluminum garnet (TAG), and a quantum dot phosphor material.

The phosphor resin layer 118 may include a polymer resin. For example, the polymer resin included in the phosphor resin layer 118 may include an epoxy resin, a silicon resin, polymethyl methacrylate (PMMA), polystyrene, polyurethane, or benzoguanamine resin, or a combination thereof. The phosphor resin layer 118 may be formed by a spray coating process which may include spraying a phosphor mixture including the polymer resin, the phosphor, filler particles, and a solvent, and undergoing a hardening process.

The lens unit 160 that surrounds the phosphor resin layer 118 and covers a portion of the upper surface of the bonded insulating layer pattern 130 may then be formed. The lens unit 160 may collect light emitted from the light emitting device 110. The lens unit 160 may be formed of at least one material selected from the group consisting of a silicon resin, an epoxy resin, plastic, and glass.

After forming the lens unit 160, the lens unit 160, the bonded insulating layer pattern 130, and the substrate 150 are diced into individual light emitting device 110 units, and separated into the light emitting device packages 100 shown in FIG. 1. The light emitting device package is manufactured at a wafer level, and divided into individual packages along a cut line C1. The light emitting device 110, the bonded insulating layer pattern 130, the through-electrode 140, the substrate 150, and the through-electrode insulating layer 152 are manufactured at the wafer level, and thus, the packages may be mass-produced, and the number of manufacturing processes may be reduced, thereby reducing processing costs and processing time.

FIGS. 8 through 12 are cross-sectional views of a method of manufacturing the light emitting device package 102 shown in FIG. 2.

Referring to FIG. 8, a plurality of via holes H2 are formed by etching the substrate 150. The etching process is performed at the wafer level, and the substrate 150 may be a silicon wafer substrate. The plurality of via holes H2 may be spaced apart by a predetermined distance from one another so as to have predetermined widths. The plurality of via holes H2 may be formed by using a wet etching method or a dry etching method. Other forming methods or types of via holes H2 are the same as those of the via hole H1 described above with reference to FIG. 4. Thus, detailed descriptions thereof are omitted here.

Referring to FIG. 9, the through-electrode insulating layer 156 is formed on an exposed surface of the substrate 150. In particular, the through-electrode insulating layer 156 may be formed on the first surface S1, the second surface S2, and the side surfaces of the substrate 150 on which the via holes H2 are formed.

The through-electrode insulating layer 156 is formed by thermally oxidating the substrate 150. In the present exemplary embodiment, the substrate 150 may be a silicon wafer. The silicon wafer substrate may be exposed to oxygen or vapor under a high temperature of about 800° C. to about 1200° C. so that a chemical reaction may occur on a surface of the silicon wafer substrate. In one or more exemplary embodiments of the present disclosure, the through-electrode insulating layer 156 may be formed by a natural oxidation method, in which the substrate 150 is placed under room temperature so that the surface of the silicon wafer substrate may be oxidated.

When comparing the thermal oxidation method or the natural oxidation method with the CVD method, the through-electrode insulating layer 156 formed by the thermal oxidation or the natural oxidation method is less subject to an uneven thickness problem such as step coverage, and the thin oxide layer having a relatively uniform thickness and high density may be formed as described above with reference to FIG. 5. The through-electrode insulating layer 156 of FIG. 9 is different from the through-electrode insulating layer 152 of FIG. 5 in that the through-electrode insulating layer 156 is formed on the first surface S1 of the substrate 150 (e.g., to a uniform thickness). In the present exemplary embodiment, the via holes H2 are formed in the substrate 150 in a state where the substrate 150 is separated from the bonded insulating layer pattern 130 (see FIG. 8), and then, the through-electrode insulating layer 156 is formed (see FIG. 9).

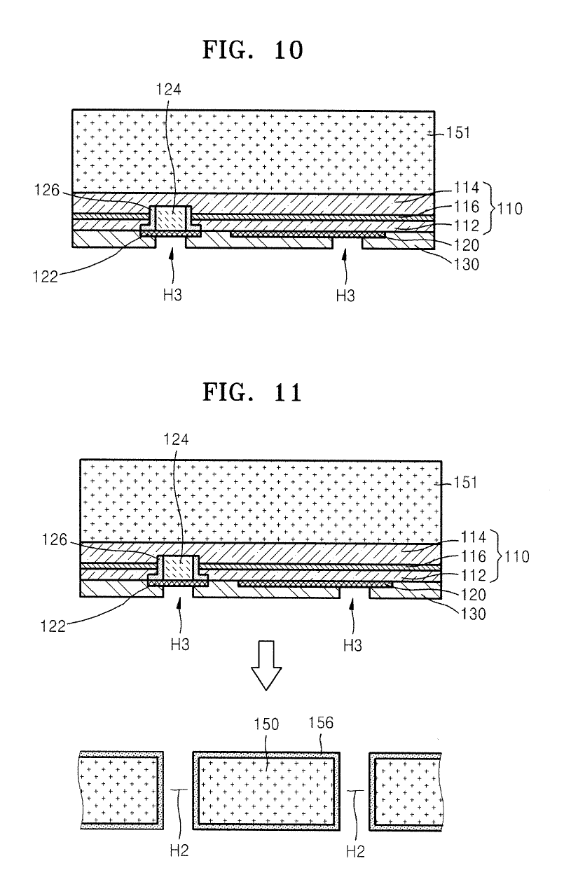

Referring to FIG. 10, the light emitting device 110 is formed on the lower surface of the growth substrate 151. The first electrode pad 120, the second electrode pad 122, and the bonded insulating layer pattern 130 that partially covers the first and second electrode pads 120 and 122 and contacts the lower surface of the light emitting device 110, are formed. The light emitting device 110, the first electrode pad 120, the second electrode pad 122, and the growth substrate 151 are the same as those shown in FIGS. 3 and 4, and thus, detailed descriptions thereof are omitted here.

Bonded via holes H3 are formed in the bonded insulating layer pattern 130 at regions in which the first electrode pad 120 and the second electrode pad 122 are formed so as to expose the lower surfaces of the first electrode pad 120 and the second electrode pad 122. The via holes H3 may be formed by anisotropically etching the bonded insulating layer pattern 130 using the wet etching or the dry etching method. If the etching is performed by using an etchant having an etch selectivity for selectively etching an insulating material only, the bonded insulating layer pattern 130 may be etched without etching the first electrode pad 120 and the second electrode pad 122. Widths of the bonded via holes H3 may be constant, and may be the same as the widths of the via holes H2 shown in FIG. 8.

Referring to FIG. 11, the growth substrate 151, the light emitting device 110, and the bonded insulating layer pattern 130 formed on the lower surface of the light emitting device 110 are mounted on the substrate 150 on which the through-electrode insulating layer 156 is formed. Here, the via holes H2 formed in the substrate 150 may overlap with the bonded via holes H3 formed in the bonded insulating layer pattern 130. Then, the lower surfaces of the first electrode pad 120 and the second electrode pad 122 may be exposed to outside through the via holes H2.

The bonded insulating layer pattern 130 and the through-electrode insulating layer 156 are formed as silicon insulating layers. In the exemplary embodiment of the present disclosure, the bonded insulating layer pattern 130 and the through-electrode insulating layer 156 are formed of silicon oxide layers. Thus, after mounting the bonded insulating layer pattern 130 on the upper surface of the through-electrode insulating layer 156, the bonded insulating layer pattern 130 may be compressed from an upper portion while increasing the temperature in order to perform the bonding operation. The bonding operation may be performed under a temperature of about 350° C. in one or more exemplary embodiments of the present disclosure.

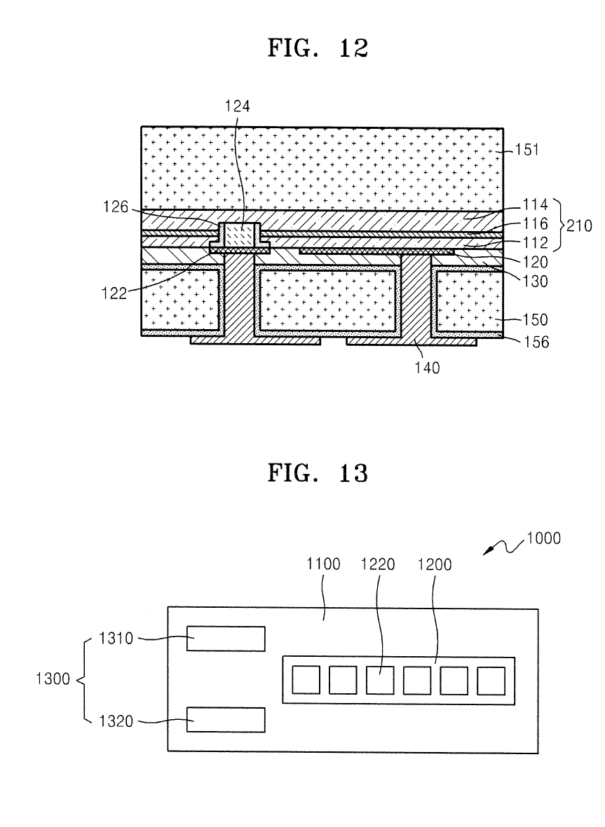

Referring to FIG. 12, the through-electrodes 140 fill the via holes H2 and have upper surfaces contacting the lower surfaces of the first electrode pad 120 and the second electrode pad 122. Shapes and formation methods of the through-electrodes 140 may be the same as those of the through-electrode 140 described with reference to FIG. 6, and thus, detailed descriptions thereof are omitted here.

Then, the growth substrate 151 is removed as described above with reference to FIG. 7, and a part of the side surface of the light emitting device 110 is etched to a predetermined depth from the side surface of the light emitting device 110. In addition, the phosphor resin layer 118 (see FIG. 2) covering the upper and side surfaces of the light emitting unit 110 is formed, and the lens unit 160 is formed to cover the phosphor resin layer 118 and a portion of an upper surface of the bonded insulating layer pattern 130. Then, a dicing process is performed, and the light emitting device package 102 shown in FIG. 2 may be obtained. Detailed descriptions about the processing order and method are described above with reference to FIG. 6, and thus, are omitted here.

FIG. 13 is a diagram of a dimming system 1000 including a light emitting device package according to an exemplary embodiment of the present disclosure.

Referring to FIG. 13, the dimming system 1000 includes a light emitting module 1200 and a power supply unit 1300 disposed on a structure 1100.

The light emitting module 1200 includes a plurality of light emitting device packages 1220. The plurality of light emitting device packages 1220 may include at least one selected from the group consisting of the light emitting devices packages 100 and 102 described above with reference to FIGS. 1 and 2.

The power supply unit 1300 includes an interface 1310 receiving a power input, and a power controller 1320 controlling an electric power supplied to the light emitting module 1200. The interface 1310 may include a fuse for blocking an over-current and an electromagnetic wave shielding filter for shielding an electromagnetic interference signal. The power controller 1320 may include a rectifying unit and an equalizing unit for converting an alternating current to a direct current when alternating current power is input as the electric power, and a constant voltage controller for converting a voltage to be suitable for the light emitting module 1200. The power supply unit 1300 may include a feedback circuit for comparing an emission amount of light from each of the plurality of light emitting device packages 1220 with a preset emission amount, and a memory device for storing information such as a desired brightness or color rendering properties.

The dimming system 1000 may be used as an indoor illumination unit such as a BLU used in a display device (e.g., a liquid crystal display (LCD) apparatus including an image display panel), a lamp, a flat panel lighting, etc., or as an outdoor illumination unit such as a signboard, a notice board, etc. Otherwise, the dimming system 1000 may be used as illumination providers for various vehicles (e.g., automobiles, vessels, or airplanes), electronic appliances such as TVs, refrigerators, etc., or medical appliances.

While the present disclosure has been particularly shown and described with reference to exemplary embodiments thereof, it will be understood that various changes in form and details may be made therein without departing from the spirit and scope of the following claims.

What is claimed is:

1. A light emitting device package comprising:
a light emitting device;
a first electrode pad and a second electrode pad formed to contact a lower surface of the light emitting device;
a bonded insulating layer pattern formed to at least partially cover side surfaces and lower surfaces of the first electrode pad and the second electrode pad;
a substrate, in which via holes are formed which penetrate the substrate from a first surface of the substrate that contacts a lower surface of the bonded insulating layer pattern to a second surface of the substrate that is opposite to the first surface;
a through-electrode disposed in each via hole and contacting the lower surface of one of the respective first electrode pad and the second electrode pad; and
a through-electrode insulating layer formed between the through-electrode and the substrate, and having an upper surface that contacts a portion of the lower surface of the bonded insulating layer pattern.

2. The light emitting device of claim 1, wherein the through-electrode insulating layer is formed on the first surface of the substrate.

3. The light emitting device of claim 1, wherein the upper surface of the through-electrode insulating layer is spaced apart from the first electrode pad and the second electrode pad.

4. The light emitting device of claim 1, wherein the bonded insulating layer pattern is disposed between the first and second electrode pads and the through-electrode insulating layer.

5. The light emitting device of claim 1, wherein the through-electrode insulating layer is formed of a silicon oxide layer that is thermally oxidated.

6. The light emitting device of claim 1, wherein the through-electrode insulating layer is formed between the substrate and the through-electrode to a uniform thickness.

7. The light emitting device of claim 1, wherein a thickness of the through-electrode insulating layer is less than a thickness of the bonded insulating layer pattern.

8. The light emitting device of claim 1, further comprising an extended through-electrode insulating layer arranged between the through-electrode and the second surface of the substrate, wherein a thickness of the extended through-electrode insulating layer is greater than a thickness of the through-electrode insulating layer.

9. The light emitting device of claim 1, wherein the light emitting device comprises:
a first nitride-based semiconductor layer;
a second nitride-based semiconductor layer disposed on the first nitride-based semiconductor layer; and
an active layer disposed between the first nitride-based semiconductor layer and the second nitride-based semiconductor layer,
wherein the active layer is formed to have a multi quantum well (MQW).

10. The light emitting device of claim 1, wherein the first electrode pad contacts a part of a lower surface of the first nitride-based semiconductor layer, and the second electrode pad contacts another part of the lower surface of the first nitride-based semiconductor layer and is electrically connected to the second nitride-based semiconductor layer by penetrating through the first nitride-based semiconductor layer and the active layer.

11. The light emitting device of claim 1, further comprising a lens unit surrounding an upper surface and side surfaces of the light emitting device, and contacting a part of an upper surface of the bonded insulating layer pattern.

12. A light emitting device package comprising:
a light emitting device;
at least two electrode pads formed on a lower surface of the light emitting device;
a substrate disposed on a lower portion of the light emitting device, and including via holes that extend between a first surface of the substrate facing the light emitting device and a second surface of the substrate that is opposite to the first surface;
a through-electrode disposed in each of the via holes and contacting a part of a lower surface of a respective one of the at least two electrode pads;
a bonded insulating layer pattern formed between the substrate and the light emitting device, and at least partially covering side surfaces and the lower surfaces of the at least two electrode pads; and
a through-electrode insulating layer formed between a lower surface of the bonded insulating layer pattern and the substrate.

13. The light emitting device of claim 12, wherein the through-electrode insulating layer is formed between the substrate and the through-electrode, and on the first surface and the second surface of the substrate.

14. The light emitting device of claim 12, wherein the through-electrode insulating layer is formed between the substrate and the through-electrode, and on the first surface and the second surface to a uniform thickness.

15. The light emitting device of claim 12, wherein the through-electrode extends from the via hole to cover a part of the second surface.

16. A light emitting device package comprising:
a substrate having a first surface and a second surface opposite the first surface;
a light emitting device disposed on the first surface of the substrate;
an electrode pad disposed on the first surface and connected to the light emitting device; and
a through-electrode disposed in the substrate and extending from the second surface to the first surface and connected to the electrode pad.

17. The light emitting device of claim 16, wherein the through-electrode extends beyond the first surface and onto the second surface.

18. The light emitting device of claim 17, further comprising a bonded insulating layer pattern disposed between the substrate and the light emitting device, said electrode pad arranged in the bonded insulating layer pattern.

19. The light emitting device of claim 16, further comprising a through-electrode insulating layer disposed in the substrate to electrically isolate the through-electrode and substrate.

20. The light emitting device of claim 17, further comprising a through-electrode insulating layer disposed in the substrate to electrically isolate the through-electrode and substrate,
wherein the through-electrode insulating layer is disposed on at least one of the first and second surfaces.
